(19) United States
(12) Patent Application Publication
(10) Pub. No.: US 2010/0237333 A1
(43) Pub. Date: Sep. 23, 2010

(54) ORGANIC COMPONENT VERTICALLY EMITTING WHITE LIGHT

(75) Inventors: Michael Thomschke, Dresden (DE); Robert Nitsche, Dresden (DE); Karl Leo, Dresden (DE)

Correspondence Address: SCHMEISER, OLSEN & WATTS, 22 CENTURY HILL DRIVE, SUITE 302, LATHAM, NY, 12110, US

(73) Assignee: TECHNISCHE UNIVERSITÄT DRESDEN, DRESDEN (DE)

(21) Appl. No.: 12/665,052

(22) PCT Filed: Jun. 20, 2008
(86) PCT No.: PCT/DE08/01016

§ 371 Date: May 4, 2010

(30) Foreign Application Priority Data
Jun. 20, 2007 (DE) 10 2007 028 821.4

(51) Int. Cl. H01L 51/52

(52) U.S. Cl. 257/40; 257/E51.018

(57) ABSTRACT

The invention relates to an organic component emitting white light upward having an electrode (1), a counter electrode (2) constructed in a transparent manner and as a cover electrode and an arrangement of organic layers (3) which is disposed in contact with and between the electrode (1) and the counter electrode (2) and which is configured to emit light when applying an electrical potential to the electrode (1) and the counter electrode (2), a cover layer (6) is applied to a side of the counter electrode (2) facing away from the arrangement of organic layers (3), having a thickness in nanometres within a layer thickness range D as follows: D=d±(0.2×d), wherein d=10.4n²−75n+150 and n is the optical refractive index of the cover layer (6).

The invention relates to the field of organic components emitting white light upward.

### BACKGROUND OF THE INVENTION

Such components are typically formed on a supporting substrate and usually comprise a base electrode and a cover electrode as well as an arrangement of thin organic layers which is disposed between and in electrical contact with the base electrode and the cover electrode. The arrangement of organic layers is configured in such a way that it emits light when applying an electrical potential to the base electrode and the cover electrode. The generation of light is effected by injecting electric charge carriers, namely electrons and holes, into the arrangement of organic layers when applying the potential, the electric charge carriers then reaching a so-called light-emitting region, also referred to as an emitter zone, and recombining therein with emission of light. If the generated light is essentially emitted through the cover electrode constructed in a transparent manner, this is called an upward emitting or top-emitting component. In contrast, in a downward or bottom-emitting component, the light emission essentially takes place through the transparent base electrode. Such components are in particular known in the form of organic light-emitting diodes which are shortened referred to as OLEDs.

The production of OLEDs is based on elaborate methods. Thus, the question of special structures which can be produced in a particularly simple and cost-efficient manner suggests itself. Upward emitting OLEDs make minor demands on the type and nature of the substrate on top of which the component is produced. In contrast, bottom-emitting OLEDs, i.e. downward emitting OLEDs, require a transparent substrate, for example in the form of glass or plastic, including a conductive coating with set basic conditions with regard to the optical and mechanical properties, such as low absorption, high transparency, conductivity, low roughness and optionally flexibility.

Moreover, organic light-emitting components for lighting or signalling purposes should generate and emit light as efficiently as possible. In this connection, the emitted light should meet different requirements, for example should the colour and light intensity be as independent as possible from the viewing direction which can be characterized by means of a viewing angle.

The ratio of the number of light quanta which can exit the component to the number of light quanta which are generated in the component is referred to as the decoupling efficiency. A very good possibility to increase this decoupling efficiency is the embedding of the component in a microcavity, that is, between two reflecting layers which act as mirrors, as it is the case with top-emitting components, in particular OLEDs. Although this construction increases the light output considerably, the angle dependency of the emission spectrum in return is worsened. Thus, this generally results not only in a reduction of the intensity at bigger viewing angles, but above all in a marked colour distortion of the emitted light.

However, the advantage of the utilization of a microcavity structure which is of use for monochromic emitting, organic components can also lead to disadvantages, in particular in top-emitting OLEDs which are to emit white light. The generation of white light in organic light-emitting components is usually implemented by means of additive mixture of colours. One option is to introduce at least two, better three different types of emitter molecules into the component, each of which emitting a certain part of the light spectrum (colour) so that they combine to generate white light. Due to the preferred emission of a particular spectral region in microcavities, it is thus rather difficult to decouple white light from the component. On the other hand, the optical path of light within a microcavity depends on the angle, resulting in a strong dependency of the emission spectrum on the viewing angle. Because of these properties, such structures obviously do not meet the required needs. A top-emitting OLED which—despite this microcavity structure—is able to emit in a wide spectral region and in this connection possesses a spectrum relatively independent from the viewing angle is thus of great interest.

Implementations of such structures with white-light emission barely exist as no promising results can be achieved due to the prior explanations. Earlier experiments and investigations (H. Riel et al.: Tuning the emission characteristics of top-emitting organic light-emitting devices by means of a dielectric capping layer: An experimental and theoretical study, J. Appl. Phys., 94 (8), 2003, pages 5290-5296; Q. Huang et al.: Performance improvement of top-emitting organic light-emitting diodes by an organic capping layer: An experimental study, J. Appl. Phys., 100 (6), 2006, 064507-1-064507-5) have shown that the emission can be changed, even increased by means of an additional organic, dielectric layer on the cover electrode without electroconductivity processes within the microcavity being affected. The additional cover layer was adapted to monochromic emitting OLEDs in terms of its properties such as thickness and refractive index to achieve a transmission of the optical subsystem which is as high as possible. However, light intensity is lost in the spectral region in the forward direction at higher viewing angles, that is, an enhancement of the microcavity effect is achieved at best.

By means of this approach and the known components, OLEDs emitting white light upward and with the desired properties cannot be realized for practical applications. Thus, previous experiments (S. F. Hsu et al.: Highly efficient top-emitting white organic electroluminescent devices, Appl. Phys. Lett., 86 (25), 2005, pages 5290-5296) indeed display white-light emission, but depend strongly on the viewing angle in terms of their spectral characteristics.

### SUMMARY OF THE INVENTION

The object of the invention is to provide an organic component emitting white light upward in which the white-light emission is improved.

According to the invention, this object is solved by an organic component emitting white light upward according to the independent claim 1. Advantageous implementations of the invention are the subject matter of dependent claims.

According to the invention, an organic component emitting white light upward is provided, having an electrode, a counter electrode constructed in a transparent manner and as a cover electrode and an arrangement of organic layers which is disposed between and in electrical contact with the electrode and the counter electrode and which is configured to emit light when applying an electrical potential to the electrode and the counter electrode, wherein a cover layer is applied to a side of the counter electrode facing away from the arrangement of organic layers, having a thickness in nanometres within a layer thickness range D as follows:

D=d±(0.2×d),

wherein d=10.4n²−75n+150 and n is the optical refractive index of the cover layer.

By means of the proposed implementation of the cover layer, it is achieved with the organic component emitting white light upward to optimize the amount of white-light emission and moreover to make the spectral emission distribution of the emitted light as independent as possible from the viewing angle. Depending on the optical refractive index n of the cover layer, the latter is formed having a thickness within a predefined layer thickness range. When forming the cover layer with such a thickness, it is no longer the case—as it is with the prior art—that only a certain wavelength range is emitted to the outside during the emission of the light having different wavelengths generated in the arrangement of organic layers, the light finally being combined to generate white light in an additive manner. The angle dependency of the emission spectrum is also minimized.

A preferred further development of the invention provides for the cover layer having a thickness within a layer thickness range D as follows: D=d±(0.1×d).

In a practical implementation of the invention, it can be provided for the optical refractive index n of the cover layer being within a range of between about 1.8 and about 2.4.

An advantageous embodiment of the invention provides for the cover layer being made of an organic material.

Preferably, a further development of the invention provides for the cover layer being produced forming an optical microcavity between an electrode region on a side of the electrode facing the arrangement of organic layers and a boundary region on a side of the cover layer facing away from the arrangement of organic layers.

In an advantageous embodiment of the invention, it can be provided for the optical microcavity being formed completely overlapping with another optical microcavity in the arrangement of organic layers.

A further development of the invention can provide for emitter materials being disposed in a light-emitting region comprised by the arrangement of organic layers, the emitter materials emitting light having different colours which is mixed in an additive manner to generate white light.

A preferred further development of the invention provides for the arrangement of organic layers comprising one or more doped organic layers which have an electrical doping.

Another preferred further development of the invention provides for the electrode being constructed in a semi-transparent manner. In this way, a semi-transparent component is provided.

### DESCRIPTION OF PREFERRED EXEMPLARY EMBODIMENTS OF THE INVENTION

In the following, the invention is explained in more detail using exemplary embodiments with reference to figures of a drawing. They show:

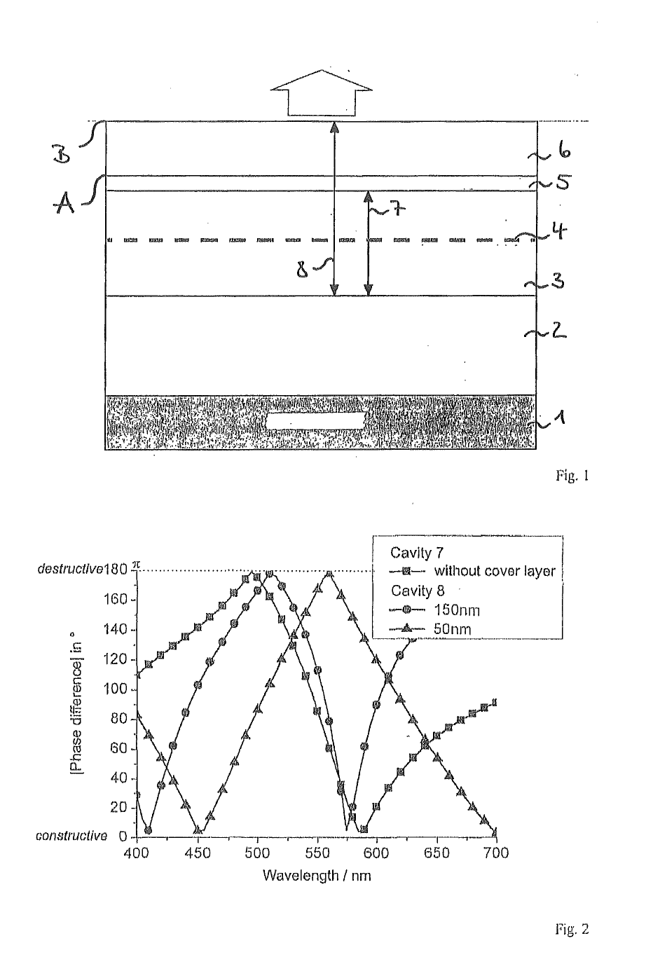

FIG. 1 a schematic illustration of a construction of an organic component emitting white light upward,

FIG. 2 a graphic representation of the phase difference as a function of the wavelength for a first and a second optical microcavity,

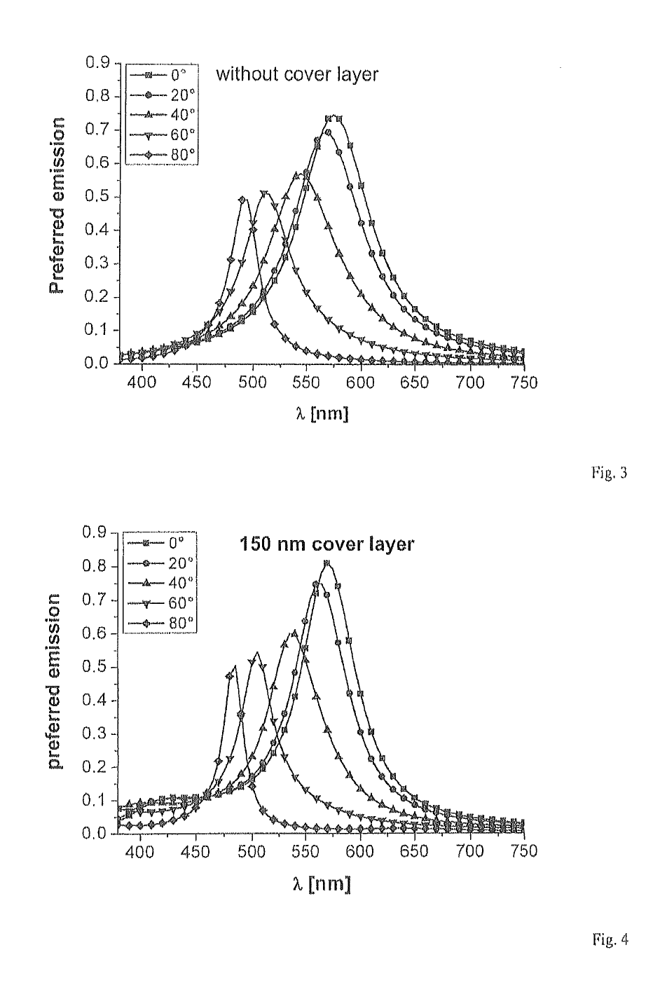

FIG. 3 a graphic representation of the relative emission as a function of the wavelength at different viewing angles for an organic component emitting white light without a cover layer,

FIG. 4 a graphic representation of the relative emission as a function of the wavelength at different viewing angles for an organic component emitting white light with a cover layer having a thickness of 150 nm,

FIG. 5 a graphic representation of the relative emission as a function of the wavelength at different viewing angles for an organic component emitting white light with a cover layer having a thickness of 50 nm and an optical refractive index of 1.8,

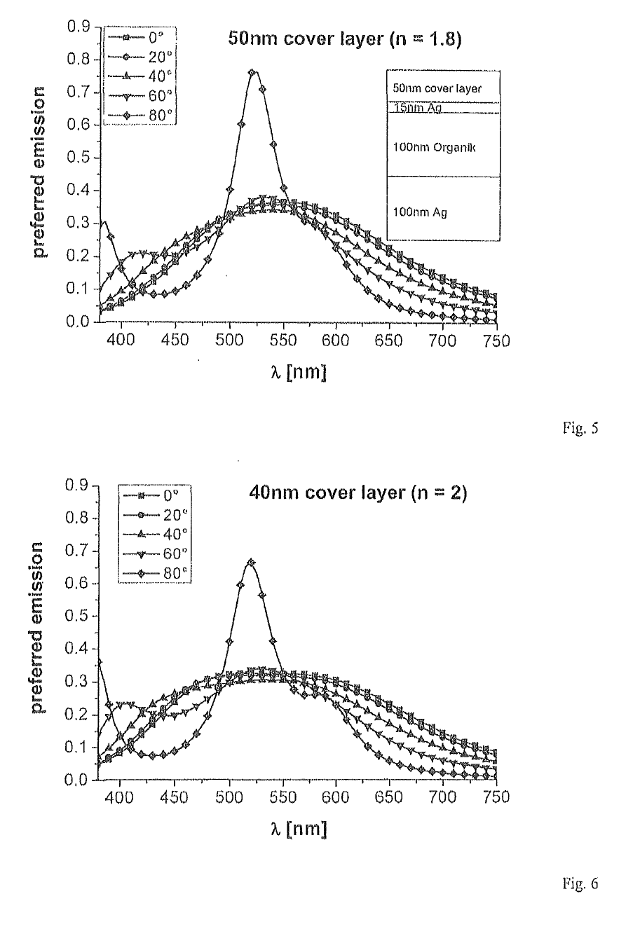

FIG. 6 a graphic representation of the relative emission as a function of the wavelength at different viewing angles for an organic component emitting white light with a cover layer having a thickness of 40 nm and an optical refractive index of 2,

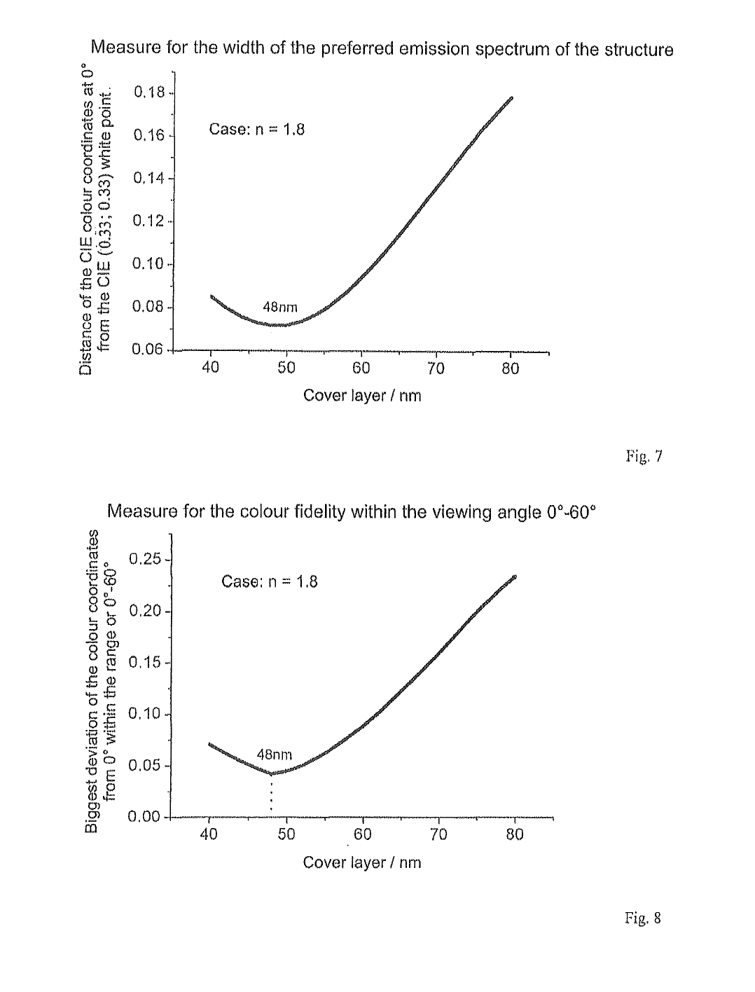

FIG. 7 a graphic representation of a distance of colour coordinates of the relative emission at 0° from colour coordinates of an ideal white-light point having the colour coordinates (0.33; 0.33) in the CIE 1931 colour space as a function of the thickness of the cover layer having the optical refractive index n=1.8 for an organic component emitting white light,

FIG. 8 a graphic representation of the maximum deviation of colour coordinates of the relative emission for a viewing angle within the range of from 0° to 60° from colour coordinates of the relative emission at 0° in the CIE 1931 colour space as a function of the thickness of the cover layer having the optical refractive index n=1.8 for an organic component emitting white light,

FIG. 9 a graphic representation of the thickness of a cover layer for an organic component emitting white light as a function of the optical refractive index of the cover layer for which the respective colour coordinates of the relative emission below a viewing angle of 0° in the CIE 1931 colour space are closest to the white point (0.33; 0.33) (ideal white-light affinity) and for which the change of the colour coordinates for the viewing angle within the range of from 0° to 60° becomes minimal (highest colour fidelity),

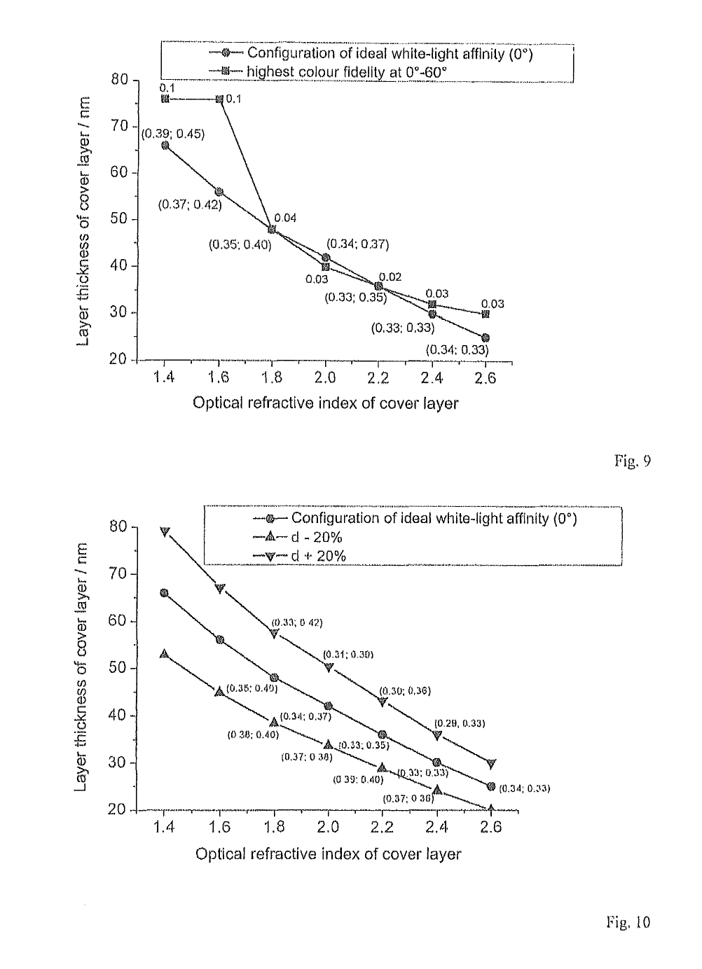

FIG. 10 a graphic representation of the thickness of the cover layer for an organic component emitting white light as a function of the optical refractive index of the cover layer for which the respective colour coordinates of the relative emission below a viewing angle of 0° in the CIE 1931 colour space are closest to the white point (0.33; 0.33) (ideal white-light affinity), and of layer thicknesses of the cover layer for an organic component emitting white light as a function of the optical refractive index of the cover layer for configurations at the tolerance limits of +/−20%,

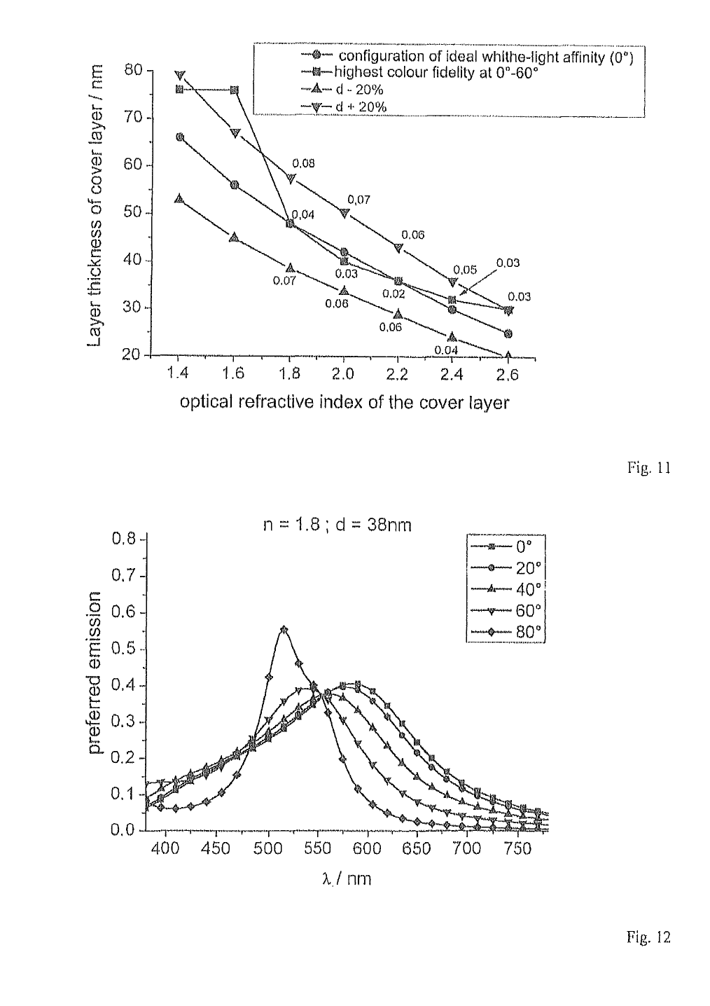

FIG. 11 a graphic representation of the thickness of the cover layer for an organic component emitting white light as a function of the optical refractive index of the cover layer for which the change of the colour coordinates for viewing angles within the range of from 0° to 60° becomes minimal (highest colour fidelity), and of the layer thicknesses of the cover layer for an organic component emitting white light as a function of the optical refractive index of the cover layer for configurations at the tolerance limits of +/−20% with the respective change of the colour coordinates for viewing angles within the range of from 0° to 60°,

FIG. 12 a graphic representation of the relative emission as a function of the wavelength at different viewing angles for an organic component emitting white light with a cover layer having a thickness of 38 nm (lower tolerance limit) and an optical refractive index of 1.8,

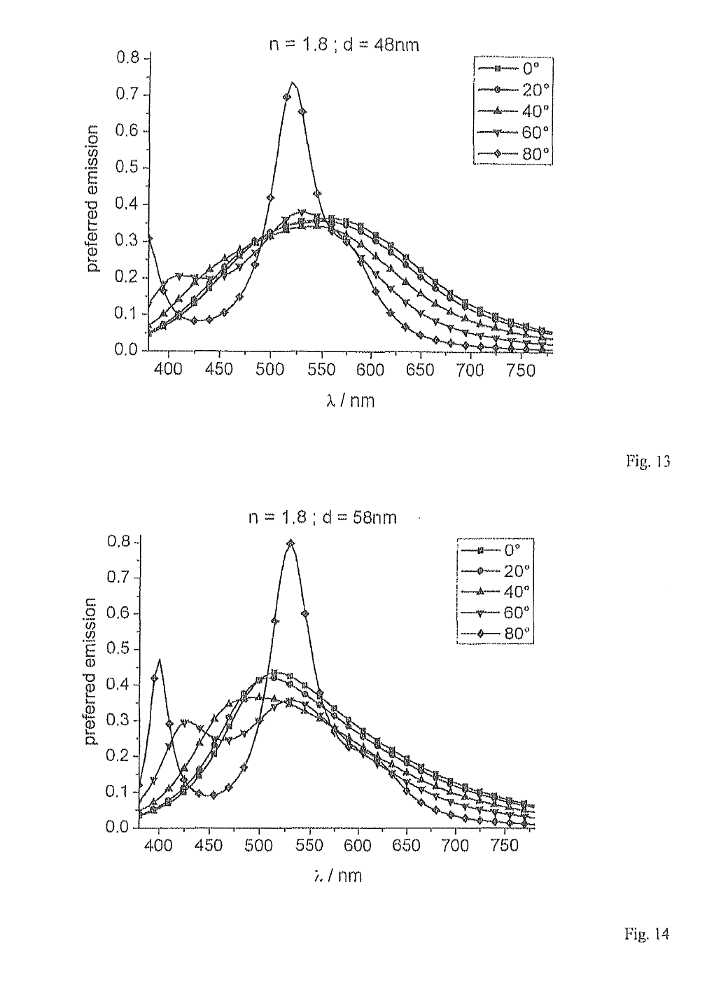

FIG. 13 a graphic representation of the relative emission as a function of the wavelength at different viewing angles for an organic component emitting white light with a cover layer having a thickness of 48 nm and an optical refractive index of 1.8, and

FIG. 14 a graphic representation of the relative emission as a function of the wavelength at different viewing angles for an organic component emitting white light with a cover layer having a thickness of 58 nm (upper tolerance limit) and an optical refractive index of 1.8.

FIG. 1 shows a schematic illustration of an organic component emitting white light upward which is thus also referred to as a top-emitting component and can in particular be implemented as an organic light-emitting diode in which a base electrode 2 is formed as an anode on a substrate 1, the base electrode being formed out of silver and having a layer thickness of at least about 80 nm, for example. A stack of organic layers 3, each of which being made of organic material, is applied to the base electrode 2, the stack preferably being formed having a layer thickness of about 100 nm and comprising a light-emitting region 4 in which charge carriers injected into the stack of organic layers 3 recombine with emission of light. The stack of organic layers 3 is followed by a cover electrode 5 in the form of a cathode which is also formed out of silver and having a layer thickness of about 15 nm, for example. The outside of the cover electrode 5 is provided with a cover layer 6 made of an organic material, the layer being formed as an additional layer. An optionally provided encapsulation of the component on the cover layer 6 is not shown in FIG. 1.

By applying the cover layer 6, several parameters of the organic component emitting white light upward are changed from an optical point of view. First of all, a boundary surface A between the cover electrode 5 and the cover layer 6 changes. Without the cover layer 6, the cover electrode 5 interfaces with air. Furthermore, a boundary surface B is formed between the cover layer 6 and air which is not present when the cover layer 6 is not provided. And finally, the optical refractive index for the region between the boundary surfaces A and B, namely the region of the cover layer 6 is changed.

Due to the provision of the cover layer 6 in the organic component emitting white light upward in accordance with FIG. 1, two overlapping optical microcavities are formed, namely a first optical microcavity 7 and a second optical microcavity 8. The optical microcavities 7, 8 influence the expansion of electromagnetic waves within the component, the electromagnetic waves representing the light generated in the light-emitting region 4. For certain wavelengths, resonance conditions result in relation to the optical microcavities 7, 8 which correspond with the formation of stationary waves. In this connection, those electromagnetic waves can achieve maximum constructive interference which display a phase difference of 2 πm after one full cycle in the optical microcavity (cf. FIG. 2, m=0, 1, 2, . . . ). This means that wave crests exactly coincide with wave crests and wave troughs exactly coincide with wave troughs. The electromagnetic waves whose wavelengths meet the resonance conditions are referred to as modes of the resonator formed by the optical microcavity (FIG. 3). The degree of reflection in the end sections of the resonator determines whether a mode is narrow-banded (high reflection) or rather wide-banded (low reflection).

In the organic component emitting white light upward in accordance with FIG. 1, the first optical microcavity 7 forms the actual resonator whose only mode is relatively narrow-banded due to the used cover electrode 5 made of metal and lies within the visible wavelength region of light. The second optical microcavity 8 is formed between the boundary surface B and the cover electrode 2. The light emitted to the outside, namely upward is in terms of its properties now no longer only determined by the first optical microcavity 7, but by both the optical microcavities 7, 8. This results in a coexistence of both the optical microcavities 7, 8 whose modes can enhance each other when their resonance conditions apply to the same wavelength region. In this case, an optimized microcavity effect for the corresponding wavelength region is achieved whereby a higher intensity of the emitted light in the forward direction is maintained (cf. FIG. 4). Such an effect has already been observed in the prior art (H. Riel et al.: Tuning the emission characteristics of top-emitting organic light-emitting devices by means of a dielectric capping layer: An experimental and theoretical study, J. Appl. Phys., 94 (8), 2003, pages 5290-5296).

If, however, the thickness of the cover layer 6 in nanometres is chosen within a layer thickness range D as follows: D=d±(0.2×d) wherein d=10.4 n²−75n+150 and n is the optical refractive index of the cover layer, an interesting effect results in that the spectral emission distribution of the emitted light is as independent as possible from the viewing angle with regard to the perpendicular of the outer surface of the cover layer 6.

In one exemplary embodiment, the cover layer 6 is formed having a refractive index of about n=1.8 and a thickness of about 50 nm

In accordance with FIGS. 5 and 6, the refractive index n of the cover layer 6 has a significant influence on the strength of resonances of both the optical microcavities 7, 8 and thus the shape of the optical spectrum. In the exemplary embodiments, a particularly good decoupling efficiency for the light generated in the stack of organic layers 3 was observed with cover layers having a refractive index n=1.8.

In the exemplary embodiment with a cover layer 6 of 50 nm which has an optical refractive index n=1.8, light in the green and yellow spectral regions is preferably emitted through the first optical microcavity 7. The part of the light which in contrast passes through the entire component, that is, the second optical microcavity 8, however, especially in the green spectral region has a phase difference within the range of π and interferes in a destructive manner, that is, light from this spectral region is not preferred by the second optical microcavity 8. However, light in the blue and red spectral regions meets the resonance condition in the second optical microcavity 8 (cf. FIG. 2) such that the result is a combination of conflicting efforts of both the optical microcavities 7, 8. Such an overlap dominated by neither of the two optical microcavities 7, 8 is responsible for the fact that the usually observed microcavity effects can hardly or not at all be observed in the proposed organic component emitting white light upward. The absence of a strong microcavity character further leads to a very weak dependency of the emission spectrum on the viewing angle (cf. FIG. 5). If moreover the entire amount of light exiting the component is considered, a maximum value for the decoupling efficiency results when using the cover layer 6 in the given manner.

The invention is explained further below with reference to FIGS. 7 to 14.

The emission behaviour when using the cover layer 6 was investigated further. It should be noted that emission affinities are used for the characterization in this connection as they define the optical properties of an upward emitting component independent of the used emitter materials. The emission affinity denotes a fictive emission spectrum which would be emitted if the molecules of the emitter materials incorporated into the stack of organic layers 2 emit a constant spectrum, i.e. a spectrum in which the intensity has the same value for all the wavelengths. It thus shows which spectral regions are preferably or are less well decoupled by the chosen component structure. No specific spectral region should be preferred for white-light emitting components, but a rather wide microcavity spectrum should be formed such that red, green and blue components of the white light are decoupled well.

The colour coordinates in the CIE colour space are used as a criterion for an affinity as wide as possible. The distance of a point in the colour space from the ideal white-light point (0.33; 0.33) can be used as a measure to numerically characterize associated spectra in respect of their colour. In this way, spectra can be compared by means of figures and the ideal layer thicknesses can be determined for relevant refractive indices of the cover layer for which the above-described effect of a wide affinity occurs (see FIG. 7).

The colour coordinates of the CIE colour space are also used for the characterization of the dependency of the affinity on the viewing angle. These colour coordinates and consequently the associated point in the colour space are going to change with the viewing angle—depending on the cover layer 6. The maximum change of the colour coordinates with regard to the colour coordinates from 0° can be considered as a measure for the colour fidelity (see FIG. 8). In this connection, it also has to be mentioned that only angles between 0° and 60° are considered here as the p-polarized proportion of the affinity generally has a big influence at greater angles. This leads to the biggest colour deviation for most component structures occurring at about 80°, i.e. at angles of rather little importance in practice.

FIG. 9 shows a graphic representation of the thickness of a cover layer for an organic component emitting white light as a function of the optical refractive index of the cover layer for which the respective colour coordinates of the relative emission below a viewing angle of 0° in the CIE 1931 colour space are closest to the white point (0.33; 0.33) (ideal white-light affinity) and for which the change of the colour coordinates for the viewing angle within the range of from 0° to 60° becomes minimal (highest colour fidelity).

Ideal cover layer thicknesses are shown which were determined numerically by means of above-mentioned criteria for ideal white-light emission and highest colour fidelity. It was found that refractive indices of the cover layer 6 of less than 1.8 provide less good results as the boundary layer between the cover layer 6 and air in this case has too little influence to effectively form the second optical microcavity 8. It can also be seen that the highest colour fidelity and the ideal white-light spectrum at different layer thicknesses occur at n=2.6. It is thus difficult to combine both desired effects, white-light spectrum and colour fidelity.

All other combinations in-between, i.e. at refractive indices n=1.8 to about 2.4, show a good correlation of the cover layer thicknesses for an ideal emission affinity for white light and highest colour fidelity. This range thus constitutes an ideal range of values for the selection of refractive index and layer thickness of the cover layer 6. An interval around the ideal cover layer thickness of ±(0.2×d) is preferred as the tolerance range for the cover layer thickness with the optical refractive index n=1.8 to 2.4.

FIG. 10 shows a graphic representation of the thickness of the cover layer for an organic component emitting white light as a function of the optical refractive index of the cover layer for which the respective colour coordinates of the relative emission below a viewing angle of 0° in the CIE 1931 colour space are closest to the white point (0.33; 0.33) (ideal white-light affinity), and of layer thicknesses of the cover layer for an organic component emitting white light as a function of the optical refractive index of the cover layer for configurations near the tolerance limits of +/−20%.

In FIG. 10, the cover layer thicknesses are applied at the lower and upper limits of the tolerance range as a function of the optical refractive index. By means of the indicated colour coordinates, the change of the emission affinity with regard to the white-light emission at the tolerance limits in comparison with the ideal value for the cover layer thickness can be tracked. The maximum change of the colour coordinates between the viewing angles of 0° and 60° in relation to 0° serves as a measure for the colour fidelity of the emission as a function of the viewing angle. This measure is shown in FIG. 11 also for the tolerance limits for component structures with a cover layer having the optical refractive index n=1.8 to 2.4. The changed emission at the tolerance limits for component structures with a cover layer having the refractive index n=1.8 can be seen in FIG. 12 and FIG. 14 in comparison with the emission of the ideal component structure in FIG. 13. The illustrations of FIG. 10 to FIG. 13 shall make clear that component structures with a cover layer within the tolerance range show the underlying effect.

The features of the invention disclosed in the above description, the claims and the drawing can be of importance both taken on their own and in any combination to implement the invention in its different embodiments.

1. An organic component emitting white light upward having an electrode (1), a counter electrode (2) constructed in a transparent manner and as a cover electrode and an arrangement of organic layers (3) which is disposed in contact with and between the electrode (1) and the counter electrode (2) and which is configured to emit light when applying an electrical potential to the electrode (1) and the counter electrode (2), wherein a cover layer (6) is applied to a side of the counter electrode (2) facing away from the arrangement of organic layers (3), having a thickness in nanometres within a layer thickness range D as follows:
D=d±(0.2×d),
wherein d=10.4n²−75n+150 and n is the optical refractive index of the cover layer (6).

2. The component according to claim 1, characterized in that the cover layer (6) has a thickness within a layer thickness range D as follows:
D=d±(0.1×d).

3. The component according to claim 1, characterized in that the optical refractive index n of the cover layer (6) is within a range of between about 1.8 and about 2.4.

4. The component according to claim 1, characterized in that the cover layer (6) is made of an organic material.

5. The component according to claim 1, characterized in that the cover layer (6) is produced forming an optical microcavity (8) between an electrode region on a side of the electrode (1) facing the arrangement of organic layers (3) and a boundary region on a side of the cover layer (6) facing away from the arrangement of organic layers (3).

6. The component according to claim 5, characterized in that the optical microcavity (8) is formed completely overlapping with another optical microcavity (7) in the arrangement of organic layers (3).

7. The component according to claim 1, characterized in that emitter materials are disposed in a light-emitting region comprised by the arrangement of organic layers (3), the emitter materials emitting light having different colours which is mixed in an additive manner to generate white light.

8. The component according to claim 1, characterized in that the arrangement of organic layers (3) comprises one or more doped organic layers which have an electrical doping.

9. The component according to claim 1, characterized in that the electrode is constructed in a semi-transparent manner.
